(19) United States
(12) Patent Application Publication
(10) Pub. No.: US 2018/0301286 A1
(43) Pub. Date: Oct. 18, 2018

(54) FABRICATION OF FULLERENE NANO-STRUCUTRES IN MIXED FILMS AND DEVICES UTILIZING FULLERENE NANO-STRUCTURES

(71) Applicant: King Abdullah University of Science and Technology, Thuwal (SA)

(72) Inventors: Yufei ZHONG, Thuwal (SA); Aram AMASSIAN, Thuwal (SA); Keisuke TAJIMA, Thuwal (SA)

(21) Appl. No.: 15/764,932

(22) PCT Filed: Sep. 30, 2016
(86) PCT No.: PCT/IB2016/055889

§ 371 Date: Mar. 30, 2018

Related U.S. Application Data
(60) Provisional application No. 62/234,966, filed on Sep. 30, 2015.

(51) Int. Cl. H01G 9/20; H01L 51/00; H01L 51/42

(52) U.S. Cl. CPC H01G 9/2009; H01L 51/4246; H01L 51/0026; H01L 51/0012

(57) ABSTRACT

Embodiments provide methods for controlling crystallization of fullerene compounds in mixed films comprising one or more polymers. Methods can include depositing fullerene mixed films comprising one or more polymers on crystalline fullerene substrates and annealing the deposited mixed films. Methods can further include one or more of exposing the annealed mixed film to UV light, and washing the annealed mixed film with a solvent. Fullerene compounds can include one or more of PCBM, PCBNB, and PCBA.

### BACKGROUND

Crystallization of organic semiconductors plays an essential role in determining performance of electronic devices such as field emission transistors (FETs) and organic solar cells (OSCs). In the case of OSCs, a typical solar cell comprises a layered architecture, including a positive electrode, a semiconducting organic active layer, and a negative electrode. The semiconductor mixture includes both n-type (i.e., electron acceptor) and p-type (i.e., electron donor) semiconductor molecules and is known as a bulk heterojunction (BHJ) layer. Controlled crystallinity of semiconductor materials within a BHJ is important due to the positive correlation between molecular order and high charge separation and charge collection efficiency.

Different methods can be used to form the BHJ layer. In solution-processed films of organic semiconductors, solvent additives and process temperatures are carefully optimized to induce controlled nucleation and crystal growth. Alternatively, materials can be crystallized by post-treating (e.g., thermal annealing and solvent vapor exposure) amorphous films, wherein random nucleation processes trigger the formation of multi-crystalline domains that significantly improve the connectivity of carrier pathways in the film. However, crystalline mixed films comprising a plurality of semiconducting materials (e.g., BHJs) are difficult to fabricate because the crystallization conditions of each material must be accommodated. The challenge involves rigorous control of crystallization, sizes of the phase separated domains, and the connectivity of each material in order to ensure high performance of a fabricated device.

Fullerene materials are commonly used in BHJ-type applications, but the above and other known fabrication methods have not provided adequate control of aggregation and/or crystallization of the fullerene within mixed films. For example, [6,6]-Phenyl-C₆₁-butyric acid methyl ester (PCBM) is a commonly used electron acceptor material in BHJs, but suitable crystallization of PCBM in BHJs has not been reported. Rather, PCBM is observed to aggregate and form a relatively pure phase separated from p-type materials (e.g., polymer) present in the BHJ. High crystallinity of the PCBM and other fullerene materials is desired in order to promote charge separation and charge collection efficiency either through increased delocalized charge transfer states at the interface, or cascade charge transfer induced by the proper energy level alignments, and continuous charge path ways.

While it is possible to crystallize PCBM, doing so requires protracted and severe thermal annealing, typically above the glass transition temperature of the polymers. Moreover, crystalline growth occurs on a macroscopic scale (e.g., 5-50 μm), and performance of the BHJ within devices such as OSCs deteriorates significantly due to the diminished interfaces between the materials. Although several approaches for suppressing macroscopic crystallization of PCBM are known, including using altering solutions with solvent additives and cross-linking components, control of PCBM nucleation and crystal growth PCBM suitable to form nanoscale crystalline structures has never been achieved in mixed films.

### SUMMARY

In general, embodiments include methods for creating various types of fullerene nano-structures in mixed material films. Methods can include forming a fullerene nano-structure in a polymer/fullerence blend. Methods can further include obtaining a fullerene nano-structure via removing polymer from the mixed film. In particular, embodiments relate to methods for creating PCBM nano-structures in mixed material films using crystalline fullerene molecule PCBM, PCBNB and PCBA as template.

Embodiments can relate to perovskite solar cells wherein the electron transporting layer comprises one or more fullerene nanostructures.

The details of one or more examples are set forth in the accompanying drawings and the description below. Other features, objects, and advantages will be apparent from the description and drawings, and from the claims.

### BRIEF DESCRIPTION OF THE DRAWINGS

FIG. 1A illustrates a block flow diagram of a method of forming a nano-structure in a polymer/fullerene blend, according to one or more embodiments.

FIG. 1B illustrates a block flow diagram of a method for obtaining a nano-structure by removing the matrix from crystalline product, according to one or more embodiments.

FIGS. 2A-C illustrate GIXRD patterns of PCBM films, according to one or more embodiments.

FIG. 3A-B illustrate cross-section SEM images of PTB7:PCBM films deposited on an annealed PCBM seed layer, according to one or more embodiments.

FIGS. 4A-C illustrate top-view SEM images of annealed PS:PCBM films, according to one or more embodiments.

FIGS. 5A-B illustrate eagle eye (45 degree) SEM images of PCBM nanostructures grown from the 80 nm PS:PCBM films and 200 nm PS:PCBM films, according to one or more embodiments.

FIG. 6A illustrates an optical microscopic image of PCBM nano-structures grown on a PCBNB seed layer, according to one or more embodiments.

FIG. 6B illustrates an scanning electron microscope image (tope view) of PCBM nano-structures grown on a PCBA seed layer, according to one or more embodiments.

FIGS. 7A-B illustrate perovskite solar cell structures with and without PCBM nanostructures, respectively, according to one or more embodiments.

FIGS. 7C-D illustrate J-V curves for perovskite devices with and without PCBM nano-structures, according to one or more embodiments.

### DETAILED DESCRIPTION

Described herein are methods for fabricating fullerene nanostructures, which are epitaxially grown on fullerene seed layers via an interface-induced growth mechanism. This interface-induced crystallization of fullerenes, such as PCBM, PCBNB, and PCBA, offers a novel approach for controlled growth of crystalline nanostructures for electron conducting materials. Such materials promise a wide range of applications, particularly for use in mixed bulk heterojunctions for photovoltaic applications.

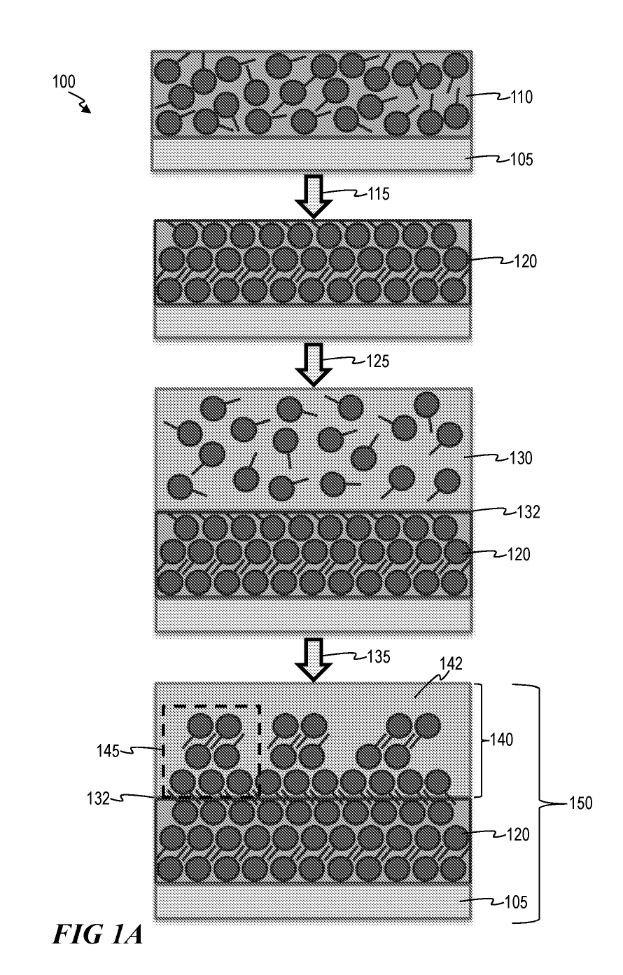

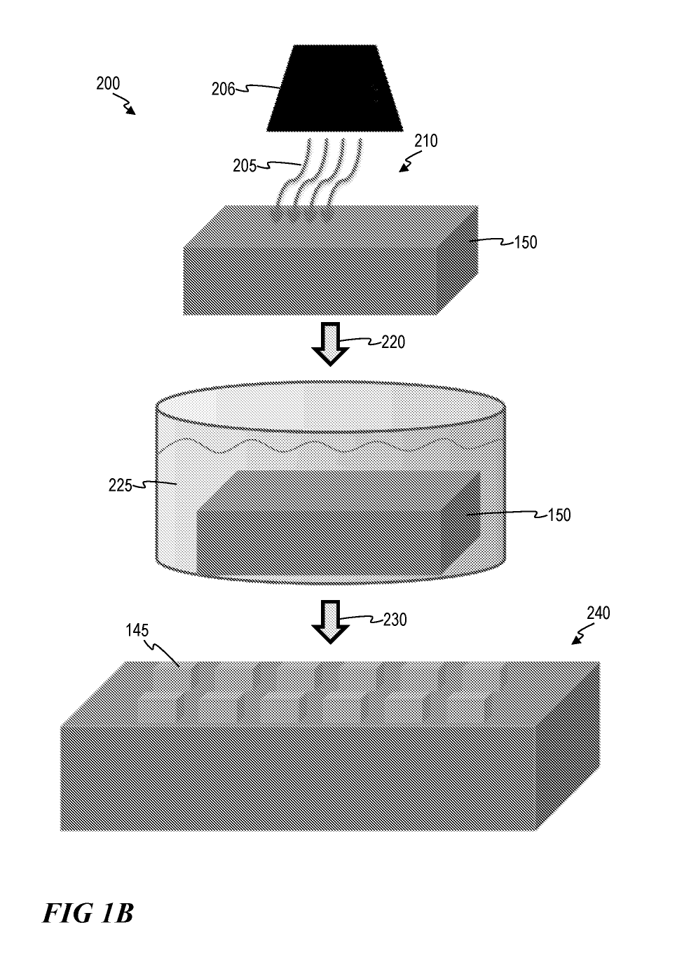

FIG. 1A illustrates a method 100 for forming a nano-structure in a polymer/fullerene blend. Method 100 comprises forming a fullerene seed layer 110 on a base substrate 105, annealing 115 the fullerene seed layer 110 to form a crystalline fullerene layer 120, applying 125 a mixed film 130 onto the crystalline fullerene layer 120, and optionally annealing 135 mixed film 130 to form a crystalline layer 140.

Fullerene seed layer 110 can fullerenes and fullerene derivatives. Fullerene is a hollow carbon molecule, and can be in the shape of a sphere, ellipsoid, and tube, among others. Spherical fullerenes are sometimes known as “buckyballs”, such as Buckminsterfullerene which is a C₆₀ spherical fullerene molecule:

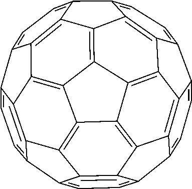 [SMILES: c1cc2c3ccc4c5ccc6c7ccc8c9ccc%10c1c1c2c2c3c4c3c5c6c4c7c8c5c9c%10c1c1c2c3c4c51]

For the purposes of this disclosure, however, “fullerene” refers to spherical fullerene molecules in general. Accordingly, “fullerene” can refer to a C₆₀, C₇₀, C₇₆, C₇₈, C₈₄, or C₉₀ spherical fullerene molecule or moiety.

Fullerene derivatives are molecules that include a spherical fullerene moiety in combination with a second organic moiety. Suitable fullerene derivatives are those which can achieve crystallinity, even if the crystallinity is low. Suitable fullerene derivatives can include methanofullerenes. Methanofullerenes refer to fullerene derivatives which comprise a cyclopropane moiety wherein one carbon of the cyclopropane is associated with the second moiety and the remaining two carbons of the cyclopropane are associated with the fullerene moiety. Suitable methanofullerenes can be characterized by the following formula:

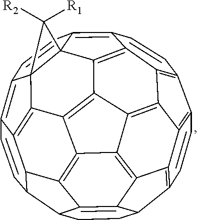

wherein R₁ and R₂ can be hydrogen or organic moieties. An organic moiety can include, for example, Cᵣ, aliphatics wherein n=1 to 20, saturated and unsaturated C_{y} cyclics wherein y=3 to 6, esters, aldehydes, ketones, amines, and combinations thereof. In a specific embodiment, one or more of R₁ and R₂ comprise a phenyl moiety. In some embodiments, suitable methanofullerenes comprise poly-methanofullerenes comprising a plurality of cyclopropane moieties configured in the same manner as with a methanofullerene.

In some embodiments, a suitable fullerene derivative can be characterized by the following formula:

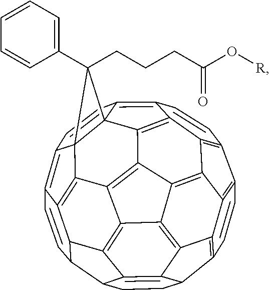

wherein R comprises hydrogen or an organic moiety. An organic moiety can include, for example, Cₙ aliphatics wherein n=1 to 20, saturated and unsaturated C_{y} cyclics wherein y=3 to 6, esters, aldehydes, ketones, amines, and combinations thereof.

Specific suitable fullerene derivatives can include [6,6]-Phenyl-C₆₁-Butyric Acid Methyl Ester (PCBM):

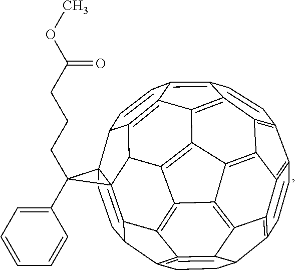

[6,6]-Phenyl-C₆₁-butyric acid n-butyl ester (PCBNB):

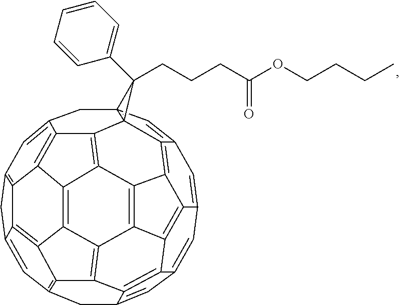

[6,6]-Phenyl C61 butyric acid (PCBA):

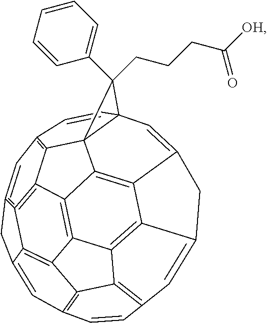

[6,6]-phenyl C₆₁ butyric acid octadecyl ester (PCBOD):

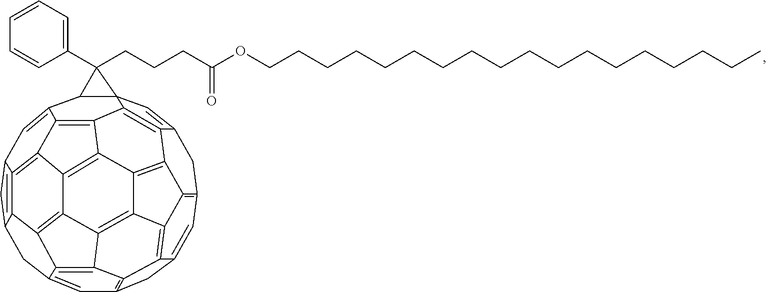

[6,6]-Phenyl-C61-butyric Acid Butyl Ester ([60]PCB-C4), [6,6]-Phenyl-C61-butyric Acid n-Octyl Ester ([60]PCB-C8), [6,6]-Phenyl-C61-butyric Acid Dodecyl Ester ([60]PCB-C12), and C60-fused N-Methylpyrrolidine-m-C12-phenyl (C60MC12).

Fullerene seed layer 110 can comprise pure fullerene, wherein pure fullerene comprises at least 90% fullerene, at least 95% fullerene, or at least 99% fullerene. Fullerene seed layer 110 can comprise pure fullerene derivatives, wherein pure fullerene derivatives comprises at least 90% fullerene derivatives, at least 95% fullerene derivatives, or at least 99% fullerene derivatives. Forming the fullerene seed layer 110 can be accomplished through any suitable method, for example by spin-coating. Fullerene seed layer 110 can optionally include a substrate 105.

Generally, annealing 115 comprises heating. Annealing 115 the fullerene seed layer 110 can comprise annealing at least about 130° C., at least about 140° C., at least about 150° C., or at least about 160° C. In one embodiment, annealing 115 can comprise annealing at about 150° C. Annealing 115 crystallizes the fullerene seed layer. Crystallization of the fullerene seed layer can occur independent from the substrate 105. Therefore, substrate 105 can comprise many materials, such as glass, TiO₂, indium tin oxide (ITO), and others.

Mixed film 130 can comprise one or more polymers and a fullerene and/or fullerene derivative. Mixed film 130 can comprise one or more methanofullerenes. For example, mixed film 130 can comprise one or more of PCBM, PCBNB, PCBA and PCBOD. In some embodiments, the fullerene and/or fullerene derivative of the mixed film 130 can be the same fullerene and/or fullerene derivative which comprises the fullerene seed layer 110. In other embodiments, the fullerene and/or fullerene derivative of the mixed film 130 can be different than the fullerene and/or fullerene derivative which comprises the fullerene seed layer 110. Mixed film 130 can be prepared before applying 125 the mixed film 130 onto the crystalline fullerene layer 120. The polymer of the mixed film 130 can comprise one or more of a crystalline polymer, a semi-crystalline polymer, or an amorphous polymer. An example of a semi-crystalline polymer is Poly({4,8-bis[(2-ethylhexyl)oxy]benzo[1,2-b:4,5-b]dithiophene-2,6-diyl}{3-fluoro-2-[(2-ethylhexyl)carbonyl]thieno[3,4-b]thiophenediyl}) (PTB7):

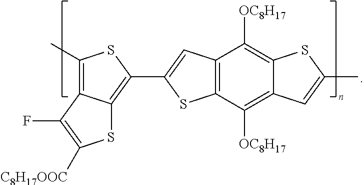

An example of a crystalline polymer is poly(3-hexylthiophene) (P3HT):

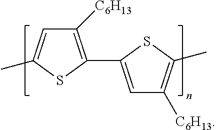

An example of an amorphous polymer is polystyrene (PS):

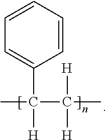

Generally, polymers can be selected based upon the diffusion characteristics of a fullerene or fullerene derivative through the polymer. In some embodiments, the mixed film 130 has a designated ratio and concentration.

Annealing 135 the mixed film 130 can comprise annealing at least about 130° C., at least about 140° C., at least about 150° C., or at least about 160° C. In one embodiment, annealing 135 can comprise annealing at about 150° C.

During and/or after annealing 135, crystalline layer 140 comprises nanostructures 145 which form in an epitaxial-like manner at the interface 132 between the fullerene seed layer 110 and the mixed film 130. Crystallization of the fullerene and/or fullerene derivatives within the mixed film 130 can be described as interface induced crystallization, wherein the crystalline fullerene layer 120 acts as a nucleation site for ordered crystalline growth of the nanostructures 145. Crystalline growth can be defined by the formation of one or a plurality of articulated nanostructures 145 which can constitute a partial formation of a crystalline layer. In addition to nanostructures 145, the crystalline layer 140 comprises matrix 142, which includes polymers and optionally uncrystallized fullerene and/or fullerene derivatives. The crystallization of the fullerene and/or fullerene derivatives is dependent upon the crystalline characteristics of the fullerene seed layer 110, but independent from the crystallinity of the polymers within the mixed film 130. Accordingly, polymers present within the matrix 142 can be crystalline, semi-crystalline, and amorphous during and after annealing 135. Generally, the layered product comprising the substrate 105, the fullerene seed layer 110, and the crystalline layer 140 comprise crystalline product 150

Process characteristics such as annealing temperature, time, and the ratio and concentration of the fullerene or fullerene derivative within the mixed film can contribute in the degree of articulation of the nanostructures 145. For example, a maximum concentration of fullerene or fullerene derivative within the mixed film 130 can prevent the formation of a fully formed crystalline layer by only providing an amount of fullerene or fullerene derivative sufficient to form a plurality of nanostructures.

The shape of individual nanostructures 145, and/or the pattern created by a plurality of nanostructures 145 can be controlled by the selection of fullerene which comprises the fullerene seed layer 110. For example, a seed layer comprising PCBA can yield nanostructures which form patterned nano-wire domains from a crystalline layer 140 that comprises PCBM. In another example, a seed layer comprising PCBNB can yield nanostructures which form patterned hexagonal domains from a crystalline layer 140 that comprises PCBM.

The size of individual nanostructures 145 can be controlled based on the ratio of fullerene and polymer within the mixed film 130. The ratio of fullerene to polymer within the mixed film 130 can be about 3:1 to about 1:3, about 2:1 to about 1:2, about 3:2 to about 2:3, or about 1:1. Additionally, the thickness (i.e., height) of the nanostructures 145 can be controlled based on the ratio of fullerene and polymer within the mixed film 130.

FIG. 1B illustrates a method 200 for obtaining a nano-structure by removing the matrix 142 from crystalline product 150. Method 200 can be used to separate the matrix 142 from the crystalline layer 140. Method 200 comprises exposing 210 the crystalline product 150 to UV light 205, contacting 220 the crystalline product 150 with a solvent 225 to yield a nanostructured product 240 comprising one or more exposed nanostructures 145. Method 200 can optionally include drying crystalline product 150 after contacting 220.

UV light 205 can comprise a wavelength between about 100 nm to about 400 nm, between about 400 nm to about 330 nm, between about 390 nm to about 340 nm, between about 380 nm to about 350 nm, or between about 370 nm to about 360 nm. In some embodiments, UV light 205 can comprise a wavelength of about 365 nm. UV light 205 can be generated by a source 206 located a distance from the crystalline product 150. In some embodiments, the distance between source 206 and the crystalline product 150 is less than about 10 cm, less than about 5 cm, less than about 4 cm, less than about 3 cm, less than about 2 cm, or less than about 1 cm. In one embodiment, the distance between source 206 and the crystalline product 150 is 1 cm. Exposing 210 occurs for a duration of time. The duration of time can be determined based on the thickness of the crystalline layer 140 of the crystalline product 150. For example, exposure time can be empirically determined by formula (1):

$$0.5 hour * \frac{thickness ( nm )}{30} \qquad ( 1 )$$

In this example, this formula is applicable at least to a UV light source with a wavelength of 365 nm and output of 4 watt, placed 1 cm away from the sample.

Contacting 220 can include spraying, dipping and the like. Solvent 225 can comprise acetone. At a minimum, a suitable solvent must dissolve the polymer in the mixed film 130. In some embodiments, a suitable solvent is one that dissolves the polymer, but not the fullerene or fullerene derivative in the mixed film 130. UV light exposure can protect the fullerene or fullerene derivative from dissolving in a solvent, so accordingly a suitable solvent can be one which dissolves the polymer and only partially dissolves the fullerene or fullerene derivative in the mixed film 130. During contacting 220, matrix 142 is removed from the crystalline product 150. Contacting 220 can occur for a duration of time sufficient to remove matrix 142. In one embodiment, contacting 220 occurs for about 1 minute. Nanostructured products formed using methods 100 and 200, such as nanostructured product 240, can be used for variety of organic electronics applications, including photovoltaics (PV), light emitting diodes (LED), and sensors, among others. For example, nanostructured products can be used as an electron transporting layer (ETL) in perovskite (methylammonium lead trihalide (CH₃NH₃PbX₃, where X is one of the following halogen ions I—, Br—, Cl—)) solar cells. Perovskite can also refer to calcium titanate (i.e., CaTiO₃), and perovskite-type structures. Perovskite type structures are those defined as ^{XII}A^{2+VI}B⁴⁺X²⁻₃, with oxygen centered in the unit cell faces.

### Example 1: Interface-Induced Crystallization and Nanostructure Formation of [6,6]-Phenyl-C61-Butyric Acid Methyl Ester (PCBM) in Polymer Blend Films

In this study, interface-induced crystallization of PCBM in mixed films with various polymers (e.g., PTB7, P3HT and PS) was achieved. A pure PCBM film thermally crystallized was used as a seed layer atop a substrate, and the mixed films of polymer and PCBM (i.e., BHJ layers) were transferred onto the seed layer. After annealing, epitaxial-like growth of PCBM crystallite happened from the bottom interface.

TiO₂ (35 nm)/ITO (100 nm)/glass substrates were prepared by spin coating TiO₂ precursor solution (NDH-510C, Nippon Soda) diluted by ethanol onto ITO substrates at a spinning rate of 3000 rpm for 30 s followed by drying at 140° C. for 40 min and calcination at 500° C. for 30 min to form TiO₂ layer. The resulting substrates were washed by ultrasonication in detergent, water, acetone and 2-propanol. Next, PCBM was spin-coated from chlorobenzene solution (10 mg/mL) onto the TiO₂/ITO substrates, and pre-annealing on selected samples was conducted on PCBM/TiO₂/ITO at 150° C. for 5 min to form crystalline PCBM layer on each substrate. Unless otherwise stated, the conditions for post-annealing in all selected samples were fixed to 150° C. for 5 min in N₂. PCBM and PCBNB were purchased from Frontier Carbon Corp., Japan (nanom spectra E100) and used without further purification. These samples were prepared for grazing angle X-ray diffraction (GIXRD) analysis. All GIXRD measurements were carried out on an X-ray diffractometer using monochromatized CuKα radiation (λ=0.154 nm) generated at 45 kV and 200 mA. GIXRD patterns were measured in the in-plane geometry at an incident angle of 0.21°. 2D GIXRD patterns were measured at an incident angle of 0.12° using synchrotron radiation at beamline BL19B2 of SPring-8. To fabricate the BHJ/PCBM/TiO₂/ITO samples, contact film transfer (CFT) was used to transfer BHJ layer onto PCBM/TiO₂/ITO samples by using poly(styrene sulfonate sodium salt) (PSS) as a sacrificial layer.

PSS/glass substrates were prepared by spin-coating PSS onto pre-cleaned glass substrates for SEM analysis. SEM was performed on a JEOL 6330F with an acceleration voltage of 3 kV. PS:PCBM//PCBM/ITO/glass samples after washing with acetone were used for top-views and bird's-eye views (45°). For the cross-section images, the samples were fabricated by mechanically breaking the samples of PTB7:PCBM//PCBM/glass. Solutions containing a mixture of polymer and PCBM (P3HT:PCBM=1:1 by weight, 20 mg/mL; PTB7:PCBM=1:1.5 by weight, 25 mg/mL; PS:PCBM=1:0.5, 1:1, 1:1.5 by weight, 20 mg/mL) were spin-coated onto the PSS/glass substrates. PTB7, P3HT and PS were purchased from 1-Materials, Canada, Rieke Metals, USA and TOSOH, Japan (Mₙ=18000, M_{w}/Mₙ=1.02, TSK standards), respectively, and used without further purification. After the film transfer, post-annealing was conducted on selected samples to induce the crystallization of PCBM in the blend layer.

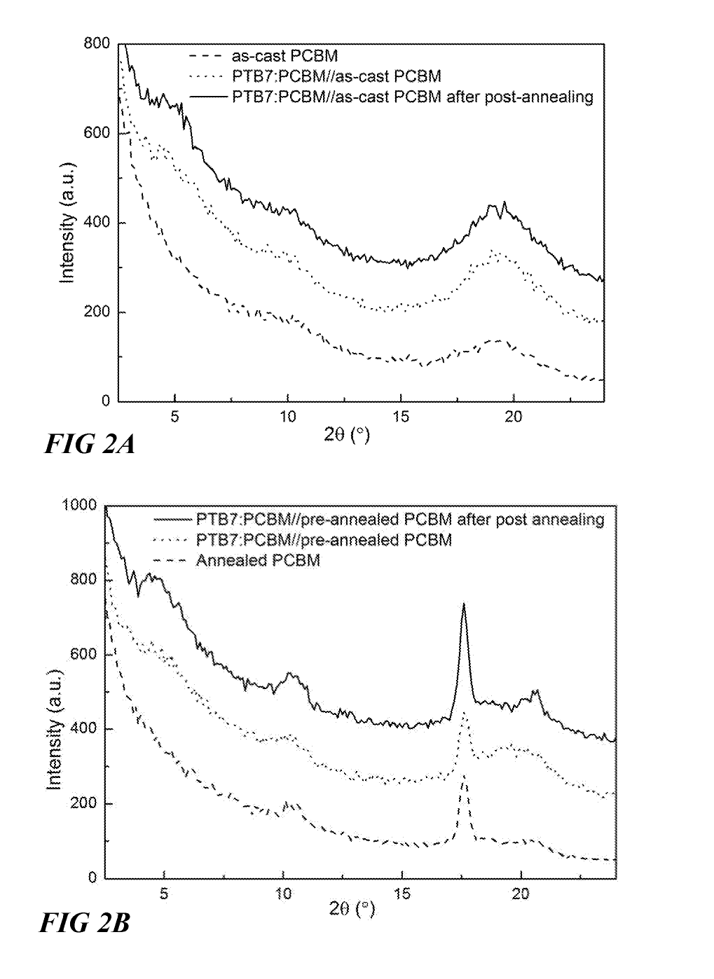

FIG. 2A illustrates GIXRD patterns of as-cast (i.e., not annealed) PCBM seed films, and as-cast PTB7:PCBM films deposited on as-cast PCBM films, and annealed PTB7:PCBM films deposited on as-cast PCBM films. The as-cast pure PCBM films (thickness: 40 nm) showed a broad peaks at 19.5°, indicating an amorphous nature.

FIG. 2B illustrates GIXRD patterns of annealed PCBM seed film, as-cast PTB7:PCBM films deposited on annealed PCBM seed film, and annealed PTB7:PCBM films deposited on annealed PCBM seed film. After annealing one or more of the PCBM seed films and/or the PTB7:PCBM films deposited on annealed PCBM seed film, sharp peaks appeared at 17.6° and broader and smaller peaks at 10.5° and 20.6°. The diminished broad peak at 19.5° observed in FIG. 2A suggests crystallization of the PCBM.

FIG. 2C illustrates GIXRD patterns of as-cast spin-coated PTB7:PCBM films deposited on TiO₂/ITO substrates, and annealed PTB7:PCBM films deposited on TiO₂/ITO substrates.

None of the PTB7:PCBM films exhibit crystallization of PCBM, before or after annealing of the PTB7:PCBM films, as indicated by no change in the halo at 19.5° after annealing of the PTB7:PCBM films. This further supports the dependence upon the seed layer for crystallization of PCBM. A slight increase of the peak intensity at 5° was observed, which can be attributed to the development of face-on lamellar structure of PTB7. It is possible annealing the PTB7:PCBM films may have altered the aggregation state of the PCBM. These results are in striking contrast to the PTB7:PCBM BHJ films transferred onto the pre-annealed and crystallized PCBM films (PTB7:PCBM//pre-annealed PCBM), which showed large changes in diffraction after post-annealing as shown in FIG. 2B.

After the film transfer, the broad peak at 19.5° again appeared due to the amorphous PCBM in the top BHJ layer. Meanwhile the intensity of the peaks from crystallized PCBM remained the same since the transfer process does not change the structure of the bottom layer and the incident angle for the GIXRD measurement (0.21°) is large enough to detect the entire films. After post-annealing of the film at 150° C., the intensity of the peaks from crystallized PCBM (17.6°, 10.5° and 21°) increased their intensity while the halo at 19.5° decreased. These results indicate that the amorphous PCBM in the BHJ layer crystallized after post-annealing only in the presence of the crystallized PCBM layer at the bottom. This strongly suggests that the crystallization occurred from the crystallized PCBM interface, possibly an epitaxial growth.

Atomic force microscopy (AFM) and optical microscopy on PTB7:PCBM//as-cast PCBM before and after annealing of the PTB7:PCBM films showed little change in surface roughness, and no macroscopic crystallization occurred in the films. This indicates that the crystallization of PCBM in PTB7:PCBM as observed in this study is different from the macroscopic phase separation often observed for OSCs when the mixed films is annealed for long durations.

Dependence of the crystallization behavior on the thickness of PTB7:PCBM layers was also investigated. When thicker BHJ layers were applied, the GIXRD peak intensities become larger, suggesting that the amount of the crystallized PCBM in BHJ increased as the film become thicker. This could imply that the induced-crystallization of PCBM happened not only in the region close to the interface but propagate to the bulk of the BHJ layer.

Dependence of the crystallization behavior on the annealing times for the PTB7:PCBM layers was also investigated. Time and temperature for the annealing were varied from 5 to 15 min and from 150° C. to 180° C. The results showed that after post-annealing at 150° C. for 5 min the crystallization of PCBM in PTB7:PCBM layer reached to its limit and the diffraction did not change further when the thickness was up to 132 nm. When the PCBM:PTB7 layer become thicker, more time was needed to complete the crystallization of PCBM (for example, more than 20 min for the layer with the thickness of 235 nm), suggesting that the diffusion of PCBM in PTB7:PCBM layer limits the rate of the crystallization.

2D GIXRD measurements of the films were performed by using synchrotron radiation. The as-cast PCBM film showed broad rings at q of 0.75 and 1.48 Å⁻¹, indicating the presence of isotropic amorphous structures. After annealing, PCBM seed layer showed a diffraction pattern with spots, indicating that there are preferred orientations of PCBM crystal domains. After deposition of PTB7:PCBM films on top of the crystallized PCBM layer, a broad ring at q=0.4 Å⁻¹ appeared which was originated from the lamellar structure of PTB7. In addition, the broad rings of amorphous PCBM appeared again due to presence of amorphous PCBM in PTB7:PCBM layer. After post-annealing, the broad rings of amorphous PCBM diminished and the diffraction spots from the PCBM crystal were intensified and slightly broadened. This result indicates that PCBM in PTB7:PCBM layer crystallized after post-annealing with the crystal structure and the orientation similar to the those of the bottom PCBM layer.

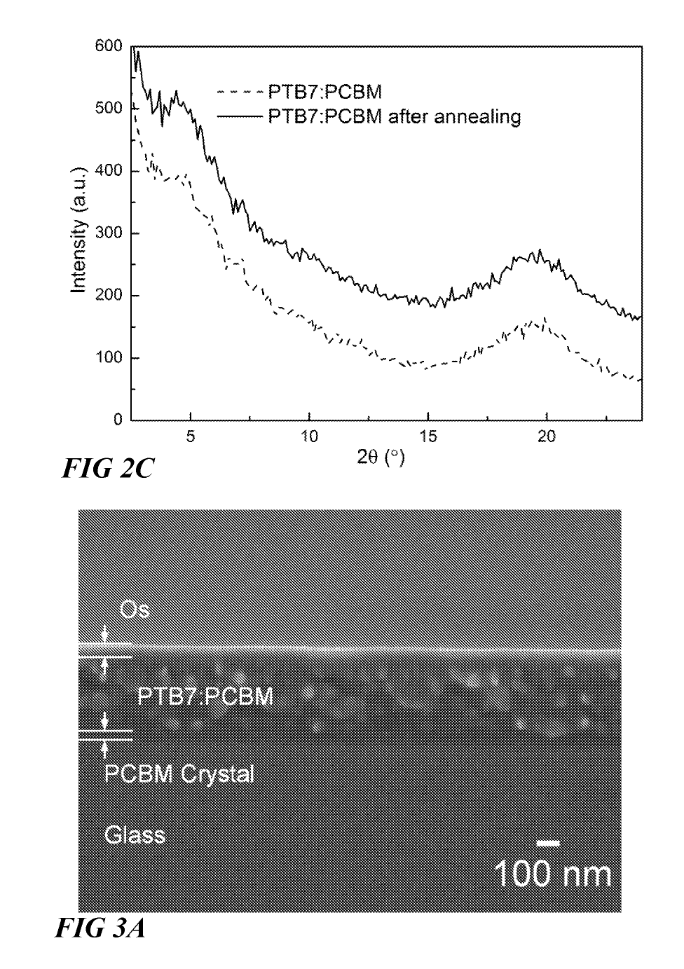

To directly observe the growth of PCBM crystal in PTB7:PCBM films, SEM was performed on the cross-section of PTB7:PCBM//pre-annealed PCBM/glass samples. FIG. 3A illustrates a cross-section SEM images of an as-cast PTB7:PCBM film deposited on an annealed PCBM seed layer. Without annealing the PTB7:PCBM film, the cross section image showed the presence of a pure PCBM layer with a thickness of 40 nm and a PTB7:PCBM layer with a thickness of 300 nm above. FIG. 3B illustrates a cross-section SEM images of an annealed PTB7:PCBM film deposited on an annealed PCBM seed layer. After annealing the PTB7:PCBM film, the SEM image showed growth of PCBM layer with the thickness of approximately 100 nm and the BHJ layer reduce its thickness to 180 nm. This suggested that PCBM in the BHJ layer crystallized from the bottom interface and obscure the original interface. The reduced thickness of PTB7:PCBM layer may be due to depletion of PCBM from the mixture film and densification by the crystallization of PTB7 as suggested by XRD.

To verify the induced crystallization of PCBM in the blend films, polymers with different properties, PS (amorphous) and P3HT (highly crystalline) were used instead of PTB7 in the mixed films as described above. 2D GIXRD results indicates that PCBM also crystallized both in PS:PCBM and P3HT:PCBM samples after post-annealing, but only when the films were in direct contact with the pre-annealed and crystallized PCBM seed layer. 2D GIXRD data of the films before and after post-annealing showed similar patterns of the diffractions from PCBM with the PTB7:PCBM case, suggesting the formation of the crystallites with the same crystal structure. These results suggest that the interface-induced crystallization of PCBM could happen in mixed films with both amorphous and crystalline polymers and could be a general phenomenon for various types of polymers. However, there are some differences in the intensity and broadness of each spot, which could suggest the difference in the sizes, the lattice constants and the orientations of the PCBM crystallites. Since the crystallization of PCBM in the mixed films should be governed by the diffusion in the polymers, flexibility of the polymer chain could largely affect the crystallization.

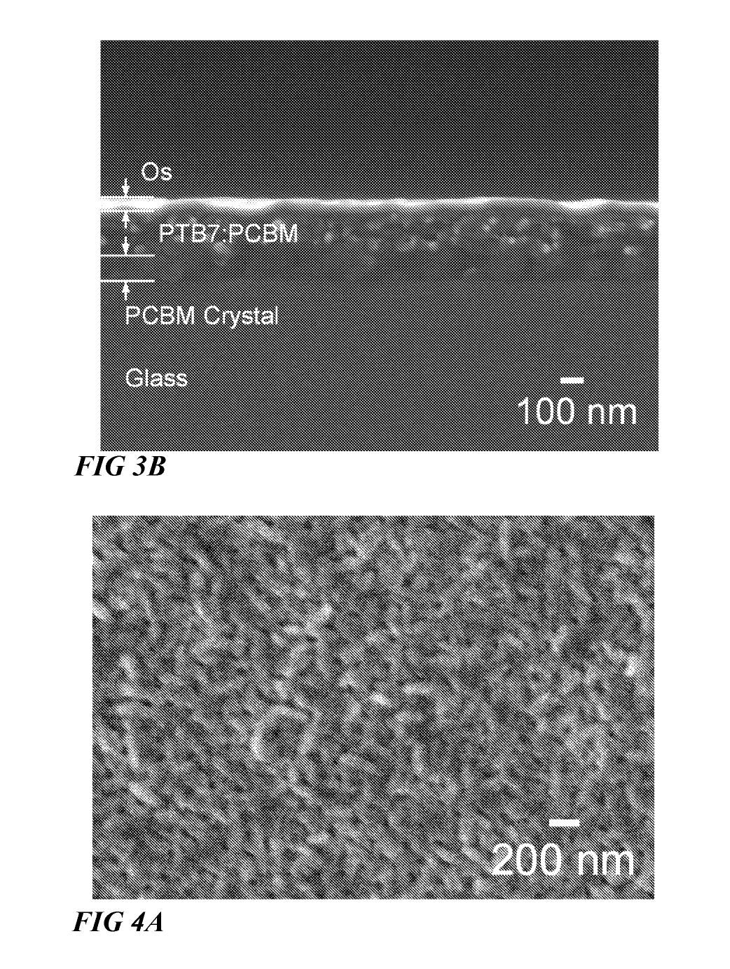

The effect of the ratio of PCBM and polymer in the mixed film on the size of crystalline structures was also investigated. PC:PCBM films with varying ratios were deposited on annealed PCBM seed layers. To obtain the direct images of the crystallized PCBM domains in the blend films, PS was selectively removed after annealing by washing with acetone. GIXRD patterns before and after washing showed that intensity of the crystalline peaks from PCBM were similar and only the amorphous halo of PCBM was noticeably. This result suggests that the crystallization happened from the bottom interface, and most of PCBM in the blend film remained on the surface after washing. FIGS. 4A-C illustrate top-view SEM images of annealed PS:PCBM films having ratios of 0.5:1, 1:1 and 1.5:1 by weight, respectively.

As shown in FIGS. 4A-C, nanorod-like structures of PCBM were formed. The shape and the length of the nanorod depended on the mixed ratios between PCBM and PS in the films. As shown in FIG. 4A, nano-rods with the length of approximately 150 nm were observed when PCBM ratio was low (PCBM:PS=0.5:1 by weight). With increased PCBM in the films, the average length of the nanorods increased up to 300 nm (PCBM:PS=1:1 by weight) and 500 nm (PCBM:PS=1.5:1 by weight) (FIGS. 4B and 4C, respectively). This could be due to the preferential growth of the PCBM crystal along to the long axis of the nanorods. More loading of PCBM in the blend film could increase the supply of PCBM molecules to the interface, resulting in the larger size of the crystallites. SEM images show that the nanorod-like PCBM structures do not have strong preferred orientations to the thickness direction. It might suggest that the pre-annealed PCBM films have surfaces consisting of the small crystallites with 2D random orientation of the growth surface. Since the 2D GIXRD patterns did not change after solvent washing to remove PS, the observed structure by SEM should be similar in the blend films of PS:PCBM before washing. UV-vis absorption spectra of the films remained similar before and after washing with acetone. This indicated that almost all the PCBM in PS:PCBM crystallized and remained on the surface as the grown crystallites.

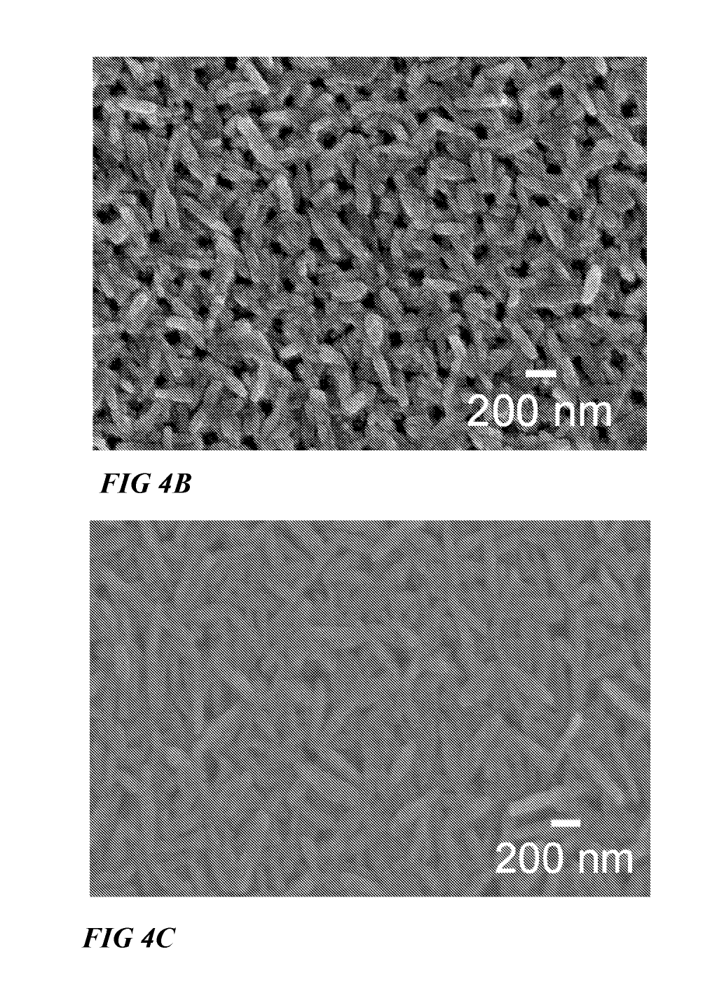

The effect of BHJ film thickness on nano-structures was also tested by depositing 80 nm PS:PCBM films and 200 nm PS:PCBM films on annealed PCBM seed layers. FIGS. 5A-B illustrate eagle eye (45 degree) SEM images of PCBM nanostructures grown from the 80 nm PS:PCBM films and 200 nm PS:PCBM films, respectively. It can be observed that thicker PCBM nano-structures were derived from thicker PS:PCBM films.

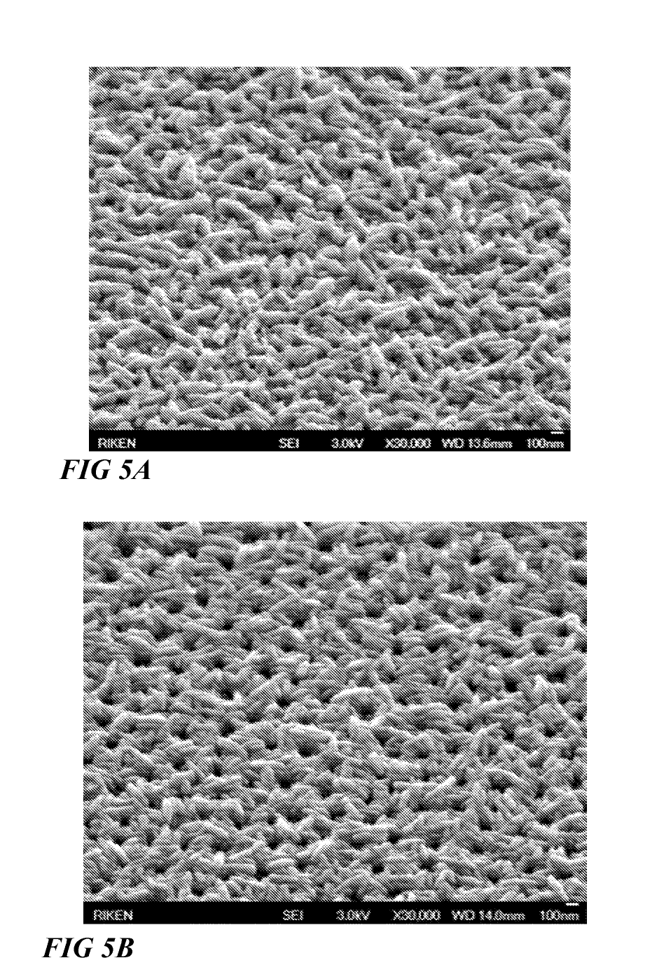

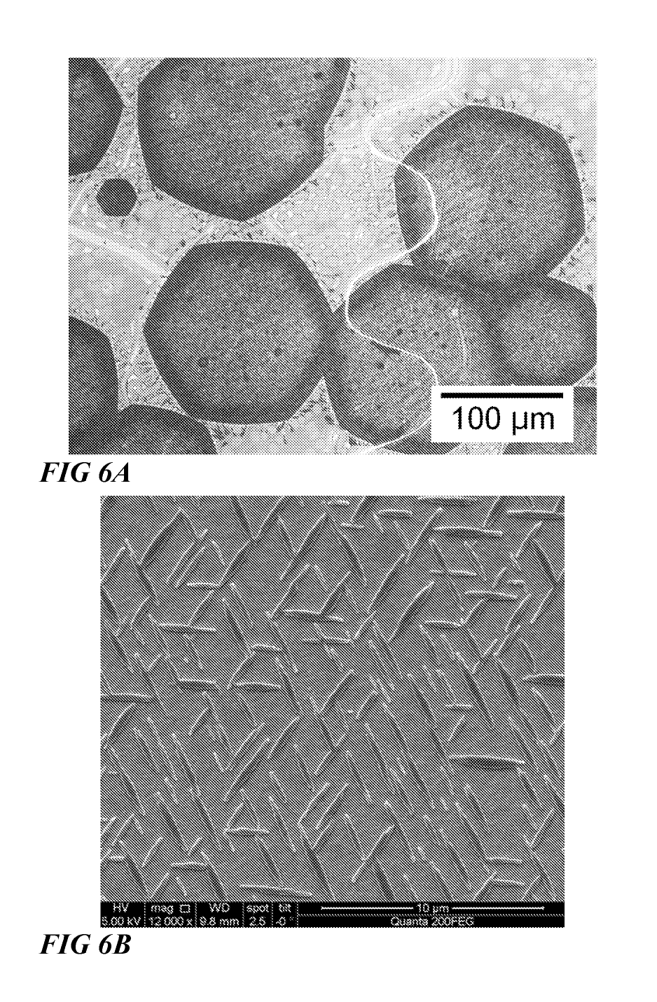

Assuming the epitaxial-like crystal growth of PCBM in BHJ from the surface of the crystallized PCBM, it was expected that the crystal face exposed to the interface could strongly affect the growth manner and the orientation of the crystals. Accordingly, different seed layer materials were also tested for use with PCBM BHJ films. FIG. 6A illustrates an optical microscopic image of PCBM nano-structures grown on a PCBNB seed layer. Large hexagonal crystals of PCBM with the size of over 100 μm were obtained by using PCBNB as a seed layer. PCBNB is structurally similar to PCBM but has a longer aliphatic tail (butyl vs. methyl). When pre-annealed PCBNB was utilized as a seed layer for PCBM mixed films, 2D GIXRD measurements showed that pre-annealed the PCBNB layer also induced crystallization of PCBM in a PTB7:PCBM layer, but the diffraction patterns are completely different from those of PTB7:PCBM//annealed PCBM after post annealing. This striking dependence of the crystallization behavior of PCBM on the seed layer indicated the importance of the structures and the orientations of the crystallites in the seed layers for the induced crystallization.

FIG. 6B illustrates SEM image (top view) of PCBM nano-structures grown on a PCBA seed layer. Patterned nano-wire domains of PCBM were obtained by using PCBA as a seed layer.

### Example 2: PCBM Nano-Structures Used as Electron Transporting Layer in Perovskite Solar Cell

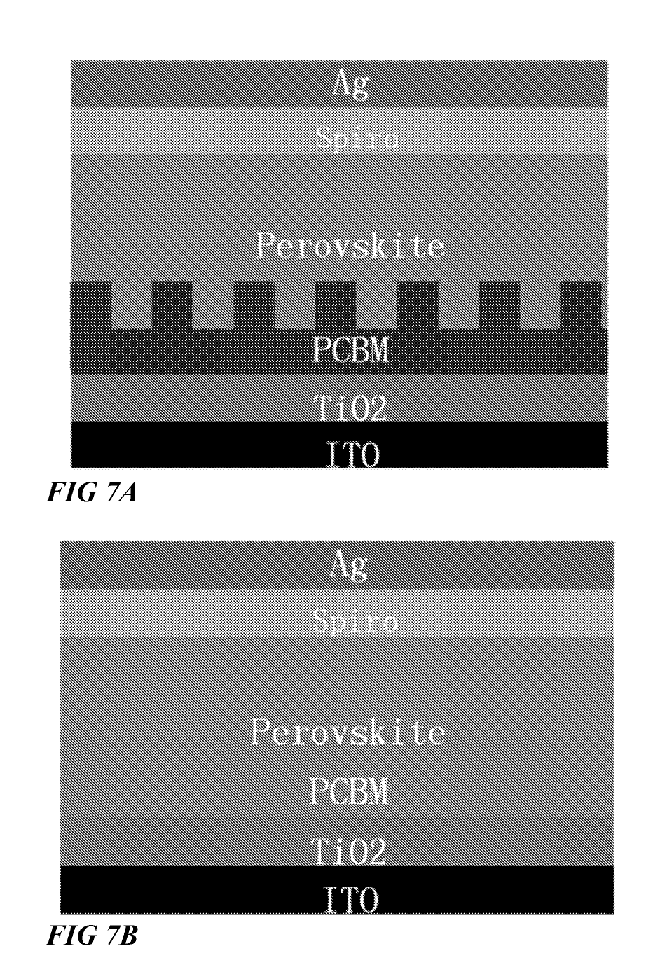

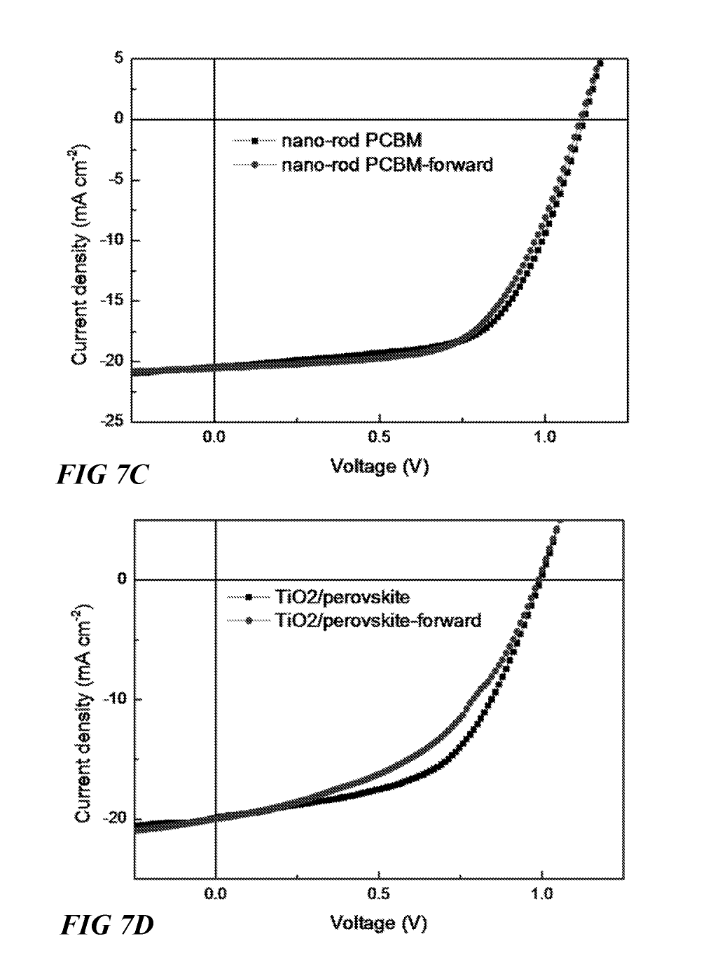

In this study, PCBM nano-structures were used as electron transporting layers (ETL) in perovskite (CH3NH3PbI3) solar cells. As shown in FIG. 7A, PCBM nano-structures were grown on an TiO₂/ITO substrate, and perovskite was subsequently deposited on top of PCBM and device was finished with spiro used as the hole transport layer (HTL) and Ag as the electrode. FIG. 7B illustrates a similarly structured perovskite solar cell without the PCBM nano-structures. FIGS. 7C-D illustrate J-V curves for perovskite devices with and without PCBM nano-structures, respectively. The detailed parameters of the devices illustrated in FIGS. 7C-D are also provided in Table 1:

TABLE 1
Parameters for perovskite devices with
and without PCBM nano-structure:

| PCBM | Scan | Voc (V) | Jsc (mA cm⁻²) | FF | PCE (%) |
|---|---|---|---|---|---|
| / | Backward | 0.97 | 19.94 | 0.54 | 10.8 |
| / | Forward | 0.98 | 19.98 | 0.46 | 9.1 |
| Nano-rod | Backward | 1.12 | 21.39 | 0.63 | 15.2 |
| Nano-rod | Forward | 1.11 | 21.21 | 0.62 | 14.7 |

As seen from Table 1 and FIGS. 7C-D, devices with PCBM nano-structure in the ETL showed much higher performance. The increased performance can be attributed to one or more of (1) PCBM has higher electron mobility than TiO₂; (2), crystallization of perovskite can be affected by PCBM nano-structures; and (3) PCBM might diffuse into perovskite grain boundaries, which could reduce traps in perovskite the film.

1. A method of fabricating a fullerene nanostructure, comprising:
depositing a blended film onto a substrate, wherein the blended film includes a polymer and fullerene;
annealing the blended film to form a crystalline layer including nanostructures and a matrix, wherein the nanostructures are formed proximate the interface of the substrate and the blended film; and
separating the matrix from the crystalline layer.

2. The method of claim 1, wherein the fullerene includes one or more of PCBM, PCBNB, and PCBA.

3. The method of claim 1, wherein the polymer includes a crystalline, semi-crystalline, or amorphous polymer.

4. The method of claim 1, wherein the substrate includes a crystalline fullerene substrate.

5. The method of claim 4, wherein the crystalline fullerene substrate includes one or more of PCBM, PCBNB, PCBA, and PCBOD.

6. The method of claim 4, wherein the crystalline fullerene substrate includes a methanofullerene.

7. The method of claim 1, wherein separating the matrix from the crystalline layer includes exposing the matrix to UV light.

8. The method of claim 7, wherein the UV light includes a wavelength between about 100 nm to about 400 nm.

9. The method of claim 1, wherein separating the matrix from the crystalline layer includes contacting the matrix with a solvent.

10. The method of claim 8, wherein the solvent includes acetone.

11. The method of claim 1, wherein separating the matrix from the crystalline layer includes exposing the matrix to UV light and subsequently contacting the matrix with a solvent.

12. The method of claim 1, wherein the fullerene includes a methanofullerene.

13. The method of claim 1, wherein the fullerene includes 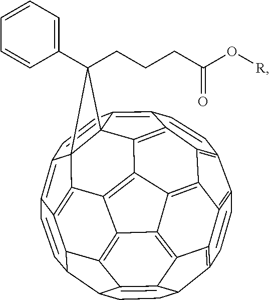
wherein R comprises hydrogen or an organic moiety.

14. A perovskite solar cell comprising:
an electron transporting layer including fullerene nanostructures.

15. The solar cell of claim 14, wherein the fullerene nanostructures include one or more of PCBM, PCBNB, and PCBA.

16. The solar cell of claim 14, further comprising a hole transport layer.

17. The solar cell of claim 14, further comprising an electrode.

18. The solar cell of claim 14, further comprising a substrate.

19. A method of fabricating a fullerene nanostructure, comprising:
depositing a blended film onto a substrate, wherein the blended film includes a polymer and a fullerene;
annealing the blended film to form a crystalline layer including nanostructures and a matrix, wherein the nanostructures are formed proximate the interface of the substrate and the blended film; and
separating the matrix from the crystalline layer by exposing the crystalline layer to UV light and contacting the crystalline layer with a solvent.

20. The method of claim 19, wherein the fullerene nanostructures include one or more of PCBM, PCBNB, and PCBA.
